(19) United States
(12) Patent Application Publication
(10) Pub. No.: US 2020/0051911 A1
(43) Pub. Date: Feb. 13, 2020

(54) CIRCUIT DEVICE PROVIDED WITH CIRCUIT BOARD AND CIRCUIT COMPONENT, AND METHOD FOR MANUFACTURING SAID CIRCUIT DEVICE

(71) Applicants: AutoNetworks Technologies, Ltd., Yokkaichi, Mie (JP); Sumitomo Wiring Systems, Ltd., Yokkaichi, Mie (JP); Sumitomo Electric Industries, Ltd., Osaka-shi, Osaka (JP)

(72) Inventors: Arinobu Nakamura, Yokkaichi, Mie (JP); Shinsuke Okumi, Yokkaichi, Mie (JP)

(21) Appl. No.: 16/606,112

(22) PCT Filed: Apr. 17, 2018
(86) PCT No.: PCT/JP2018/015788

§ 371 Date: Oct. 17, 2019

(30) Foreign Application Priority Data
Apr. 28, 2017 (JP) 2017-089605

(51) Int. Cl. H01L 23/522; H01L 25/07; H01L 23/528; H01L 21/768

(52) U.S. Cl. CPC H01L 23/5226; H01L 25/07; H01L 21/76838; H01L 21/76802; H01L 23/528

(57) ABSTRACT

A circuit device includes a circuit board and a conductive plate that are laminated via an insulating layer, and a circuit component. A conductive path is formed on the insulating layer using a conductive adhesive, and a portion of the conductive path is interposed between the insulating layer and the back side of the circuit board. A first terminal of the circuit component is electrically connected to the conductive path, and a second terminal is electrically connected to the conductive plate through a missing portion formed in the insulating layer. The conductive pattern extends to the back side of the circuit board, and the extended conductive pattern and the conductive path are adhered to each other where the respective surfaces overlap each other.

### CROSS-REFERENCE TO RELATED APPLICATIONS

This application is the U.S. national stage of PCT/JP2018/015788 filed on Apr. 17, 2018, which claims priority of Japanese Patent Application No. JP 2017-089605 filed on Apr. 28, 2017, the contents of which are incorporated herein.

### TECHNICAL FIELD

The present disclosure relates to a circuit device provided with a circuit board and a circuit component, and a method for manufacturing the circuit device.

### BACKGROUND

A circuit board on which circuit components such as FETs and a controller for controlling the FETs are mounted and that is provided with a conductive pattern is sometimes interposed in a power circuit for connecting a power source and a load. The conductive pattern electrically connects the circuit components and the controller to each other, and the circuit board supplies and cuts off power to the load.

A FET includes terminals (a drain terminal, a source terminal) that are connected to conductive plates (bus bars) that are part of the power circuit and through which electric current flows between the power source and the load, and a terminal (a gate terminal) to which a control signal output from the controller is input.

Whether electric current is supplied or cut off between the drain terminal and the source terminal that are connected to the conductive plates is controlled by a control signal that is input to the gate terminal (e.g., see JP 2003-164040A).

In the circuit device disclosed in JP 2003-164040A, the conductive plates are laminated, via an insulating layer, on the back side of the circuit board on which the controller is mounted, and the FETs are placed on the conductive plates, which are exposed from open holes provided in the circuit board. Also, the drain terminal and the source terminal are connected to the conductive plates, and the gate terminal is connected to the conductive pattern formed on the front side of the circuit board.

Terminals of a FET include connection ends that protrude outward from side surfaces of the packaging thereof and are flush with each other. With the circuit device disclosed in JP 2003-164040A, although the drain terminal and the source terminal can be easily connected, in order to connect the gate terminal and the conductive pattern formed on the front side of the circuit board, the gate terminal needs to be bent in order to handle a level difference amounting to the thickness of the circuit board, which is time-consuming. Also, if the circuit board is thick or the length of a terminal extending from the packaging is short, it may be difficult to connect them.

### SUMMARY

This disclosure aims to provide a circuit device in which circuit components and a circuit board can be reliably connected without bending terminals.

A circuit device according to one aspect of this disclosure includes a circuit board having a front side provided with a conductive pattern, a conductive plate laminated on a back side of the circuit board via an insulating layer, and a circuit component that is placed on the conductive plate through an open hole passing through the circuit board from a front side of the circuit board to the back side, and that is provided with a first terminal and a second terminal. The circuit device includes a conductive path that is formed on the insulating layer using a conductive adhesive, a portion of the conductive path is interposed between the insulating layer and the back side of the circuit board, the first terminal is electrically connected to the conductive path, the second terminal is electrically connected to the conductive plate through a missing portion formed in the insulating layer, and the conductive pattern extends to the back side of the circuit board and is adhered to the conductive path.

A method for manufacturing a circuit device according to one aspect of this disclosure includes a step of forming an insulating layer on a conductive plate, a step of applying a conductive adhesive onto the insulating layer and forming a linear conductive path, a step of placing and adhering a circuit board provided with a conductive pattern extending from a front side to a back side of the circuit board on/to the insulating layer with the back side of the circuit board facing the insulating layer, and pressing and adhering the conductive pattern extending to the back side of the circuit board to one end portion of the conductive path with the conductive pattern and the one end portion overlapping each other, and a step of placing a circuit component in a region of the conductive plate located on the insulating layer side on which the circuit board is not placed, and placing a leading end portion of a terminal of the circuit component on another end portion of the conductive path.

### Advantageous Effects of Disclosure

According to this disclosure, because the first terminal (terminal) of a circuit component is connected to the conductive path formed on the insulating layer, it is possible to eliminate the need for bending the terminal to adjust it to the thickness of the circuit board.

### BRIEF DESCRIPTION OF DRAWINGS

FIG. 1 is a cross-sectional side view of a circuit device according to Embodiment 1.

FIG. 2 is a plane view of the circuit device according to Embodiment 1.

FIG. 3 is a schematic circuit diagram of the circuit device according to Embodiment 1.

FIG. 4 is a diagram illustrating a method for manufacturing a circuit device.

FIG. 5 is a schematic cross-sectional side view of a circuit device according to Embodiment 2.

### DETAILED DESCRIPTION OF PREFERRED EMBODIMENTS

First, embodiments of this disclosure will be described below. At least portions of embodiments described below may also be combined.

A circuit device according to one aspect of this disclosure includes a circuit board having a front side provided with a conductive pattern, a conductive plate laminated on a back side of the circuit board via an insulating layer, and a circuit component that is placed on the conductive plate through an open hole passing through the circuit board from the front side of the circuit board to the back side, and that is provided with a first terminal and a second terminal, in which the circuit device includes a conductive path that is formed on the insulating layer using a conductive adhesive, a portion of the conductive path is interposed between the insulating layer and the back side of the circuit board, the first terminal is electrically connected to the conductive path, the second terminal is electrically connected to the conductive plate through a missing portion formed in the insulating layer, and the conductive pattern extends to the back side of the circuit board and is adhered to the conductive path.

According to this aspect, because the first terminal of the circuit component is connected to the conductive path formed on the insulating layer, it is possible to eliminate the need for bending the terminal to adjust it to the thickness of the circuit board.

A portion of the conductive path is interposed between the insulating layer and the back side of the circuit board, and a layer structure is formed in the order of the insulating layer, the conductive path, and the circuit board. Because the conductive pattern extends to the back side of the circuit board, and the conductive path and the conductive pattern are adhered to each other where respective surfaces overlap each other, it is possible to ensure a reliable electrical connection. Also, because the conductive path is formed using a conductive adhesive, it is possible to easily adhere the conductive path and the conductive pattern to each other.

The conductive adhesive is preferably a thermosetting conductive paste.

According to this aspect, because the conductive adhesive is a thermosetting conductive paste, it is possible to easily form a conductive path having good conductivity by applying or printing the thermosetting conductive paste to/on the insulating layer and heating the thermosetting conductive paste.

A configuration is preferable in which the conductive path is linearly formed, the width of the conductive path is larger on another end side of the conductive path than on one end side of the conductive path, the one end side being on the first terminal side, and the other end side being interposed between the insulating layer and the back side of the circuit board.

According to this aspect, because the conductive path has a linear shape, the width of the conductive path overlapping the back side of the circuit board is larger than the width thereof on the gate terminal side, a surface of the conductive pattern extending to the back side and a surface of the conductive path can reliably be laid on one another.

A configuration is preferable in which the circuit board is provided with a through-hole passing through the circuit board from the front side to the back side, and the conductive pattern extends to the back side of the circuit board through the through-hole.

According to this aspect, it is possible to easily extend the conductive pattern formed on the front side to the back side of the circuit board through the through-hole provided in the circuit board.

A configuration is preferable in which the circuit component is a semiconductor switch, and the first terminal is a control signal receiving terminal for receiving a control signal for turning ON or OFF the semiconductor switch.

According to this aspect, when the first terminal is a control signal receiving terminal, it is possible to form a path for a control signal that is input to the semiconductor switch between the semiconductor switch and the circuit board.

A method for manufacturing a circuit device according to one aspect of this disclosure includes a step of forming an insulating layer on a conductive plate, a step of applying a conductive adhesive onto the insulating layer and forming a linear conductive path, a step of placing and adhering a circuit board provided with a conductive pattern extending from a front side to a back side of the circuit board on/to the insulating layer with the back side of the circuit board facing the insulating layer, and pressing and adhering the conductive pattern extending to the back side of the circuit board to one end portion of the conductive path with the conductive pattern and the one end portion overlapping each other, and a step of placing a circuit component in a region of the conductive plate located on the insulating layer side on which the circuit board is not placed, and placing a leading end portion of a terminal of the circuit component on another end portion of the conductive path.

According to this aspect, using a conductive adhesive makes it possible to manufacture a circuit device according to one aspect of this disclosure using a simple manufacturing method for applying the conductive adhesive to an insulating layer.

Specific examples of a circuit device provided with a circuit board and a circuit component, and a method for manufacturing the circuit device according to an embodiment of this disclosure will be described with reference to the drawings below. Note that the present disclosure is not limited to these examples, and is defined by the claims, and all changes that come within the meaning and range of equivalency of the claims are intended to be embraced therein.

### Embodiment 1

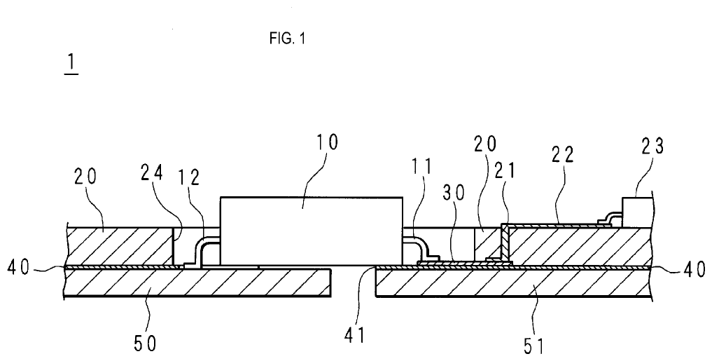

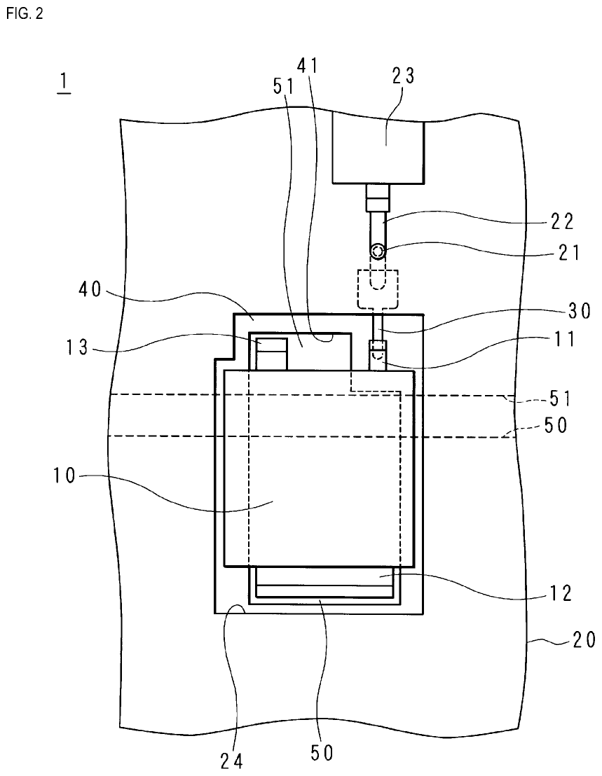

FIG. 1 is a cross-sectional side view of a circuit device according to Embodiment 1. FIG. 2 is a plan view of the circuit device according to Embodiment 1. The circuit device 1 includes a FET 10 as a circuit component and a drain terminal bus bar 50 and a source terminal bus bar 51 as conductive plates. The FET 10 may be an n-channel FET or a p-channel FET. Note that the circuit component is not limited to the FET 10, and may also be a semiconductor switch such as an IGBT or a bipolar transistor, a voltage converter or an AC-DC converter such as a regulator. The following describes a case where the FET 10 is an n-channel FET.

A plurality of circuit components (not shown) including a controller 23 are mounted on the front side of the circuit board 20, and a conductive pattern (land) 22 for connecting these circuit components is formed. The conductive pattern 22 is formed by printing a conductor such as copper foil on the circuit board 20, for example. The controller 23 is constituted by a microcomputer or a control IC, for example, and outputs a control signal such as a pulse signal from a terminal included in the controller 23, the control signal controlling the FET 10.

The drain terminal bus bar 50 and the source terminal bus bar 51 are arranged side-by-side with their edges facing each other, forming a gap between the edges, and are laminated on the back side of the circuit board 20 via an insulating layer 40. The source terminal bus bar 51 and the drain terminal bus bar 50 are plates made of a metal having good conductivity, such as copper, which is suitable for letting a large current flow, such as a motor drive current.

The insulating layer 40 is formed through coating with an insulating resin material or attachment of an insulating film, for example. The insulating layer 40 is provided with a missing portion 41 for exposing portions of the source terminal bus bar 51 and the drain terminal bus bar 50, the missing portion 41 extending between the drain terminal bus bar 50 and the source terminal bus bar 51 that are disposed side-by-side.

The circuit board 20 is provided with an open hole 24 passing through the circuit board 20 from its front side to its back side. The circuit board 20 is placed on the drain terminal bus bar 50 and the source terminal bus bar 51 with the open hole 24 being positioned relative to the missing portion 41, and opposing portions of the drain terminal bus bar 50 and the source terminal bus bar 51 are exposed from the open hole 24 and the missing portion 41.

The FET 10 includes the gate terminal 11, the drain terminal 12, and the source terminal 13. The gate terminal 11 and the source terminal 13 are arranged side-by-side on one side surface of the packaging of the FET 10 and protrude outward therefrom. The drain terminal 12 protrudes outward from the other side surface located opposite the one side surface. The terminals (11, 12, 13) include leading end portions that are bent and extend toward the bottom surface of the packaging, and are flush with each other. Also, the leading end portions and the bottom surface of the packaging are flush with each other. The FET 10 is placed through the open hole 24 on the source terminal bus bar 51 and the drain terminal bus bar 50 exposed from the open hole 24 to extend across opposing portions of their edges.

The drain terminal 12 is electrically connected to the drain terminal bus bar 50 exposed from the missing portion 41 through the missing portion 41 formed in the insulating layer 40. The source terminal 13 is electrically connected to the source terminal bus bar 51 exposed from the missing portion 41 through the missing portion 41 formed in the insulating layer 40. The gate terminal 11 is electrically connected to the conductive path 30 provided on the insulating layer 40.

The conductive path 30 is provided on the insulating layer 40 from a position at which the gate terminal 11 is connected to the conductive path 30 to a position at which the back side of the circuit board 20 overlaps the conductive path 30. As shown in FIG. 2, the conductive path 30 is linearly formed, and the width of the conductive path 30 is larger on the other end side of the conductive path 30 on which the back side of the circuit board 20 overlaps the conductive path 30 than on one end side of the conductive path 30, the one end side being on the gate terminal 11 side.

The conductive path 30 located on the circuit board 20 side is interposed between the insulating layer 40 and the circuit board 20. Also, the conductive pattern 22 formed on the front side of the circuit board 20 extends to the back side through the through-hole 21 formed in the circuit board 20 at a position at which the back side overlaps the conductive path 30.

The conductive path 30 interposed between the insulating layer 40 and the circuit board 20 and the conductive pattern 22 extending to the back side are adhered to each other where the respective surfaces overlap each other, and are electrically connected to each other. A layer structure is formed in the order of the insulating layer 40, the conductive path 30, and the conductive pattern 22.

The conductive path 30 is formed using a thermosetting conductive paste. The thermosetting conductive paste is a conductive adhesive obtained by dispersing conductive fillers such as minute metal particles in a thermosetting resin such as polyester, an epoxy resin, or a heat resistant urethane resin, and mixing them, for example. The thermosetting conductive paste is applied or printed onto/on the insulating layer 40, and is cured through heating at a temperature of about 100 to 200° C. for 15 to 30 minutes, thus improving its conductivity. Note that the conductive adhesive is not limited to a thermosetting conductive paste, and may also be a low-temperature curing conductive adhesive, or a one-component conductive adhesive.

The leading end portion of the gate terminal 11 is placed on the conductive path 30 on the gate terminal 11 side, and the gate terminal 11 and the conductive path 30 are electrically connected to each other through solder printing, for example. The gate terminal 11 of the FET 10 and the controller 23 are electrically connected to each other via the conductive path 30 and the conductive pattern 22.

In the circuit device 1 configured as described above, a control signal output from the controller 23 is input to the FET 10 from the gate terminal 11 through the conductive pattern 22 and the conductive path 30, and thus the FET 10 is controlled.

The FET 10 is placed on the source terminal bus bar 51 and the drain terminal bus bar 50 through the open hole 24 and the missing portion 41. Also, the leading end portion of the gate terminal 11 is placed on the conductive path 30 formed on the insulating layer 40 using the thermosetting conductive paste in the form of a thin film, and is electrically connected to the conductive path 30 through solder printing, for example.

Because there is no level difference amounting to the thickness of the circuit board 20 between the FET 10 and the leading end portion of the gate terminal 11, the need to bend the gate terminal 11 can be eliminated. Even if the FET 10 has short terminals, it can be used, and it is possible to reduce wiring loss caused by the terminals. Also, even if the circuit board 20 is thick, it is possible to electrically connect the gate terminal 11 of the FET 10 to the circuit board 20.

As a result of interposing the conductive path 30 between the insulating layer 40 and the circuit board 20, the conductive pattern 22 that is formed on the front side of the circuit board 20 and extends to the back side of the circuit board 20 and the conductive path 30 are adhered to each other where the respective surfaces overlap each other, and are electrically connected to each other.

A relay component such as a lead wire or a connection piece for connecting the gate terminal 11 and the conductive pattern 22 formed on the front side of the circuit board 20 is not required, and the gate terminal 11 and the conductive pattern 22 can be electrically connected to each other reliably.

Also, the conductive path 30 has a linear shape, and the width of the conductive path 30 overlapping the back side of the circuit board 20 is larger than the width of the circuit board 20 on the gate terminal 11 side. Thus, a surface of the conductive pattern 22 extending to the back side and a surface of the conductive path 30 can reliably be laid on one another.

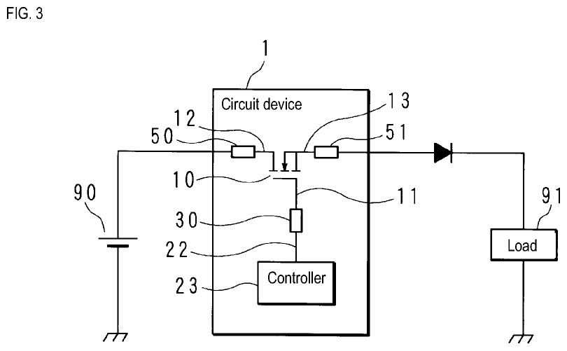

FIG. 3 is a schematic circuit diagram of the circuit device 1 according to Embodiment 1. The circuit device 1 is provided in a vehicle (not shown), and used to supply and cut off power between an in-vehicle power supply 90 and an in-vehicle load 91, for example.

The drain terminal 12 of the FET 10 is electrically connected to a positive electrode of the in-vehicle power supply 90 via the drain terminal bus bar 50. The source terminal 13 of the FET 10 is electrically connected to the in-vehicle load 91 via the source terminal bus bar 51. The gate terminal 11 of the FET 10 is electrically connected to the controller 23 via the conductive path 30 and the conductive pattern 22.

Thus, if a control signal is output from the controller 23 and the FET 10 is ON, an electric current supplied from the in-vehicle power supply 90 flows through the drain terminal bus bar 50, the FET 10, and the source terminal bus bar 51 in this order, and power is supplied to the in-vehicle load 91. If the FET 10 is OFF, the flow of an electric current between the in-vehicle power supply 90 and the in-vehicle load 91 can be interrupted.

### Manufacturing Process

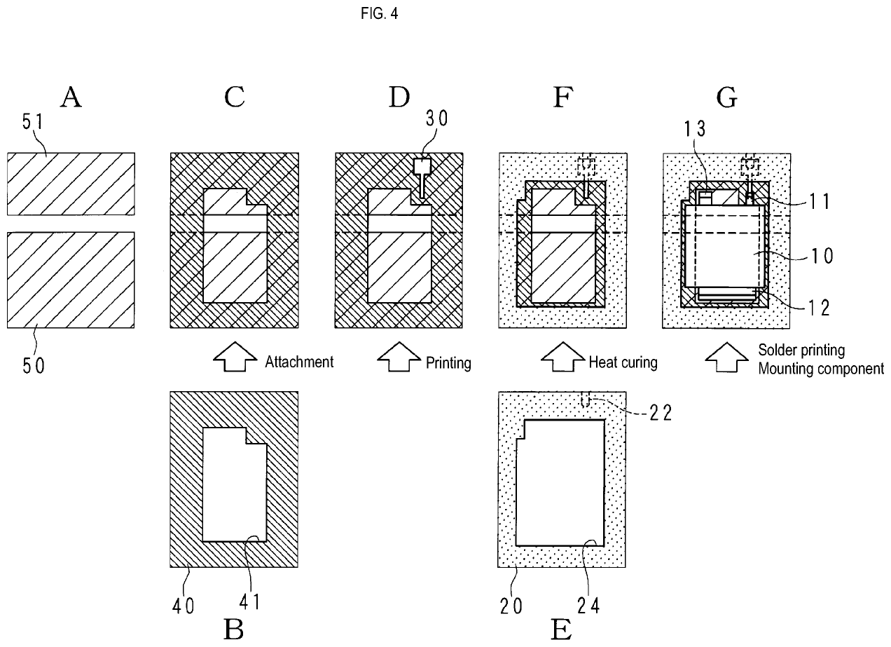

FIG. 4 is a diagram illustrating a method for manufacturing the circuit device according to Embodiment 1. The method for manufacturing the circuit device 1 according to Embodiment 1 will be described below with reference to FIG. 4. Note that the drain terminal bus bar 50, the source terminal bus bar 51, and the insulating layer 40 are hatched in directions opposite to each other, and overlapping portions (cross-hatched portions) can be recognized.

First, edges of the drain terminal bus bar 50 and the source terminal bus bar 51 are arranged side-by-side with their edges facing each other, forming a gap between the edges (see FIG. 4A).

Then, the insulating layer 40 provided with the missing portion 41 and constituted by an insulating film is prepared (see FIG. 4B). Opposing portions of the drain terminal bus bar 50 and the source terminal bus bar 51 are aligned with this missing portion 41, and the insulating layer 40 is attached to the drain terminal bus bar 50 and the source terminal bus bar 51 (see FIG. 4C). When the insulating layer 40 is attached, a position to which the insulating layer 40 is attached is set such that the drain terminal bus bar 50 and the source terminal bus bar 51 are exposed from the missing portion 41. The insulating film is attached using an adhesive applied to the insulating film. The adhesive exhibits adhesion through heating or pressing, for example.

The missing portion 41 has a rectangular wider portion and a rectangular narrower portion, and the wider portion and the narrower portion are connected to each other. A portion of the wider portion is located on the drain terminal bus bar 50 side, and the remaining portion of the wider portion and the narrower portion are located on the source terminal bus bar 51 side.

Then, the conductive path 30 is formed on the insulating layer 40 (see FIG. 4D). The conductive path 30 is formed by printing an adhesive thermosetting conductive paste on the insulating layer 40. The thermosetting conductive paste is printed in an appropriate length from a region surrounded by edges of the narrower portion and the wider portion of the missing portion 41 in the direction opposite the drain terminal bus bar 50. The conductive path 30 has a linear shape, and the width of another end of the conductive path 30 is larger than the width of one end of the conductive path 30 located on the missing portion 41 side. The printing may be screen printing. Also, the thermosetting conductive paste may be applied to the insulating layer 40 using a mask, for example.

Then, the circuit board 20 is prepared which is provided with the open hole 24 having a size to include the missing portion 41 (see FIG. 4E). Then, the back side of the circuit board 20 is placed on and fixed to surfaces of the drain terminal bus bar 50 and the source terminal bus bar 51 provided with the insulating layer 40 (see FIG. 4F). Note that the circuit board 20 is dotted, and a cross-hatching portion is omitted.

The back side of the circuit board 20 is fixed thereto by applying an adhesive to the back side of the circuit board 20, for example. When the circuit board is placed thereon, the open hole 24 and the missing portion 41 are positioned such that the drain terminal bus bar 50 and the source terminal bus bar 51 are exposed from the open hole 24 and the missing portion 41. Also, a portion of the conductive path 30 is positioned to be exposed from the open hole 24. Further, a portion of the conductive pattern 22 extending to the back side of the circuit board 20 and a portion of the conductive path 30 having a larger width are positioned to be in contact with and overlap each other, and then are welded with pressure.

Then, as a result of heating the conductive path 30 formed by the thermosetting conductive paste, the conductive path 30 is cured, the conductive pattern 22 extending to the back side and the conductive path 30 are adhered to each other and are electrically connected to each other.

Then, the FET 10 is placed on, extending from the drain terminal bus bar 50 to the source terminal bus bar 51 that are exposed from the open hole 24 and the missing portion 41 (see FIG. 4G).

At this time, the leading end portion of the source terminal 13 protruding from one side surface of the packaging is placed on the source terminal bus bar 51, and the leading end portion of the drain terminal 12 protruding from the other side surface is placed on the drain terminal bus bar 50. Also, the leading end portion of the gate terminal 11 protruding from the one side surface of the packaging is placed on the conductive path 30 exposed from the open hole 24.

Then, the leading end portion of the gate terminal 11 is electrically connected to the conductive path 30, the drain terminal 12 is electrically connected to the drain terminal bus bar 50, and the source terminal 13 is electrically connected to the source terminal bus bar 51 through solder printing, for example.

### Embodiment 2

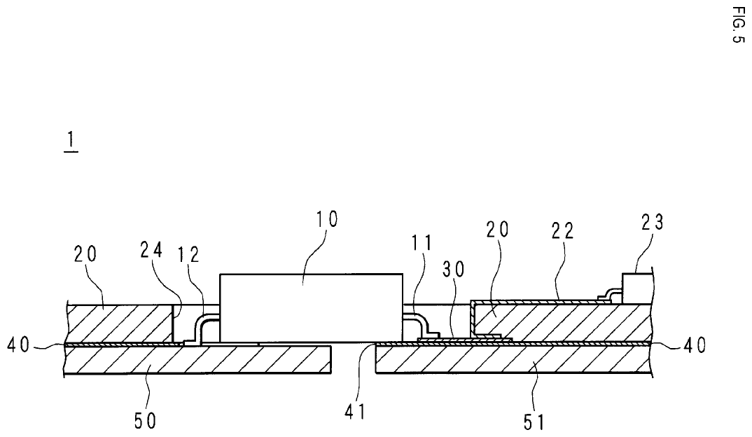

A circuit device 1 according to Embodiment 2 has the same configuration as that of the circuit device 1 according to Embodiment 1, except that the conductive pattern 22 extends in a different manner. FIG. 5 is a schematic cross-sectional side view of the circuit device 1 according to Embodiment 2. Constituent elements shared with Embodiment 1 are given the same reference numerals as those in FIG. 1 and will not be described.

A conductive pattern 22 according to Embodiment 2 extends from the front side to the back side of the circuit board 20 via a side surface located between the front side and the back side. Also, a portion of the conductive pattern 22 extending to the back side and the conductive path 30 interposed between the insulating layer 40 and the circuit board 20 are adhered to each other where the respective surfaces overlap each other, and are electrically connected to each other.

Thus, a through-hole 21 in the circuit board 20 is not required. Also, an end portion of the conductive pattern 22 on the conductive path 30 side may extend on the side surface until the end portion is flush with the back side of the circuit board 20, and the end portion and the conductive path 30 may be adhered to each other.

The embodiments that were disclosed are to be considered in all aspects to be illustrative and not restrictive. The scope of the present disclosure is defined by the claims and not by the above description, and all changes that come within the meaning and range of equivalency of the claims are intended to be embraced therein.

1. A circuit device comprising:
a circuit board having a front side provided with a conductive pattern;
a conductive plate laminated on a back side of the circuit board via an insulating layer; and
a circuit component that is placed on the conductive plate through an open hole passing through the circuit board from the front side of the circuit board to the back side, and that is provided with a first terminal and a second terminal,
wherein the circuit device comprises a conductive path that is formed on the insulating layer using a conductive adhesive, and a portion of the conductive path is interposed between the insulating layer and the back side of the circuit board,
the first terminal is electrically connected to the conductive path,
the second terminal is electrically connected to the conductive plate through a missing portion formed in the insulating layer, the conductive pattern extends to the back side of the circuit board, and
the conductive path interposed between the insulating layer and the circuit board and the conductive pattern extending to the back side of the circuit board are adhered to each other where the respective surfaces overlap each other, and are electrically connected to each other, and a layer structure is formed in the order of the insulating layer, the conductive path, and the conductive pattern.

2. The circuit device according to claim 1, wherein the conductive adhesive is a thermosetting conductive paste.

3. The circuit device according to claim 1, wherein the conductive path is linearly formed, the width of the conductive path is larger on another end side of the conductive path than on one end side of the conductive path, the one end side being on the first terminal side, and the other end side being interposed between the insulating layer and the back side of the circuit board.

4. The circuit device according to claim 1,
wherein the circuit board is provided with a through-hole passing through the circuit board from the front side to the back side, and
the conductive pattern extends to the back side of the circuit board through the through-hole.

5. The circuit device according to claim 1,
wherein the circuit component is a semiconductor switch, and
the first terminal is a control signal receiving terminal for receiving a control signal for turning ON or OFF the semiconductor switch.

6. A method for manufacturing a circuit device, comprising:
a step of forming an insulating layer on a conductive plate;
a step of applying a conductive adhesive onto the insulating layer and forming a linear conductive path;
a step of placing and adhering a circuit board provided with a conductive pattern extending from a front side to a back side of the circuit board on/to the insulating layer with the back side of the circuit board facing the insulating layer, pressing, adhering, and electrically connecting the conductive pattern extending to the back side of the circuit board to one end portion of the conductive path that is interposed between the insulating layer and the circuit board with the conductive pattern and the one end portion overlapping each other, and forming a layer structure in the order of the insulating layer, the conductive path, and the conductive pattern; and
a step of placing a circuit component in a region of the conductive plate located on the insulating layer side on which the circuit board is not placed, and placing a leading end portion of a terminal of the circuit component on another end portion of the conductive path.

8. The circuit device according to claim 2, wherein the conductive path is linearly formed, the width of the conductive path is larger on another end side of the conductive path than on one end side of the conductive path, the one end side being on the first terminal side, and the other end side being interposed between the insulating layer and the back side of the circuit board.

9. The circuit device according to claim 2,
wherein the circuit board is provided with a through-hole passing through the circuit board from the front side to the back side, and
the conductive pattern extends to the back side of the circuit board through the through-hole.

10. The circuit device according to claim 3,
wherein the circuit board is provided with a through-hole passing through the circuit board from the front side to the back side, and
the conductive pattern extends to the back side of the circuit board through the through-hole.

11. The circuit device according to claim 2,
wherein the circuit component is a semiconductor switch, and
the first terminal is a control signal receiving terminal for receiving a control signal for turning ON or OFF the semiconductor switch.

12. The circuit device according to claim 3,
wherein the circuit component is a semiconductor switch, and
the first terminal is a control signal receiving terminal for receiving a control signal for turning ON or OFF the semiconductor switch.

13. The circuit device according to claim 4,
wherein the circuit component is a semiconductor switch, and
the first terminal is a control signal receiving terminal for receiving a control signal for turning ON or OFF the semiconductor switch.
